(19) United States
(12) Patent Application Publication
(10) Pub. No.: US 2004/0226655 A1
(43) Pub. Date: Nov. 18, 2004

(54) Substrate processing apparatus

(75) Inventors: Itsuki Kajino, Kyoto (JP); Takashi Kawamura, Kyoto (JP); Kaori Asakino, Kyoto (JP)

Correspondence Address: OSTROLENK FABER GERB & SOFFEN, 1180 AVENUE OF THE AMERICAS, NEW YORK, NY, 100368403

(73) Assignee: Dainippon Screen Mfg. Co., Ltd.

(21) Appl. No.: 10/811,285

(22) Filed: Mar. 26, 2004

(30) Foreign Application Priority Data
Mar. 26, 2003 (JP) 2003-084720

(51) Int. Cl. H01L 21/8238

(52) U.S. Cl. 156/345.11

(57) ABSTRACT

A substrate processing apparatus is provided with a spin base for rotationally holding a substrate, an atmosphere cutoff plate for cutting off a top surface of the substrate from the outer atmosphere, a splash guard for receiving a processing solution spun off from the substrate or the like, a guard up-and-down moving mechanism for vertically moving the splash guard. In performing processing with a processing solution while rotating a substrate, the splash guard is disposed by the guard up-and-down moving mechanism so that the level of a top surface of the splash guard should not be higher than the level of a top surface of the atmosphere cutoff plate and it is thereby possible to prevent the atmosphere above the atmosphere cutoff plate from being involved in the recovery duct through rotation of the atmosphere cutoff plate. This makes it possible to provide a substrate processing apparatus capable of preventing redeposition of processing solution removed from a substrate by centrifugal forces onto the substrate.

### BACKGROUND OF THE INVENTION

1. Field of the Invention

The present invention relates to a substrate processing apparatus which performs processing on semiconductor substrates, glass substrates for liquid crystal display, glass substrates for photomask, substrates for optical disk or the like (hereinafter, referred to simply as“substrates”) held on a rotating base with processing solutions such as chemical liquids while rotating the substrates in a horizontal plane, and more particularly to a sheet-fed substrate processing apparatus.

2. Description of the Background Art

As this type of sheet-fed substrate processing apparatus, conventionally, a both-side cleaning apparatus or a bevel etching apparatus have been used. The both-side cleaning apparatus is used for cleaning both front and back surfaces of a substrate by supplying a predetermined processing solution from both the front and back sides while rotating the substrate in a horizontal plane. On the other hand, the bevel etching apparatus is used for etching of a peripheral portion of a substrate by supplying a predetermined processing solution from its back side and rounding part of the processing solution to the peripheral portion of its front surface of the substrate while rotating the substrate in a horizontal plane.

FIG. 5 is a longitudinal section showing a sheet-fed substrate processing apparatus in the background art. The substrate processing apparatus is used for cleaning both the front and back surfaces of a substrate W by supplying chemical liquid and pure water (hereinafter, chemical liquid and pure water are referred to generally as“processing solution”) from upper and lower sides of the substrate W.

The substrate processing apparatus of FIG. 5 mainly comprises a spin base 100 for holding the substrate W in a horizontal position, a motor 102 for rotating the spin base 100 through a rotation axis 110, an atmosphere cutoff plate 120 facing the spin base 100, a motor 129 for rotating the atmosphere cutoff plate 120 through a rotation axis 121 and a cup 130 surrounding the atmosphere around the substrate W held on the spin base 100.

On a top surface of the spin base 100, a plurality of chuck pins 101 are provided, standing. A plurality of chuck pins 101 hold edge portions of the substrate W, to keep the substrate W in a horizontal position away from the spin base 100 with a predetermined space. The substrate W is held with its front surface upward and its back surface downward. At that time, in order to surely hold the edge portions of the substrate W, upper tip portions of the chuck pins 101 slightly protrude from the top surface of the substrate W.

The rotation axis 110 is provided, extending downward from the center portion of the lower side of the spin base 100. The inside of the rotation axis 110 is hollow, in which a processing solution nozzle 112 is inserted. The motor 102 is communicated with the rotation axis 110 through a belt drive mechanism 103. When the motor 102 is driven, the driving force is transferred to the rotation axis 110 through the belt drive mechanism 103, and the substrate W held by the chuck pins 101, together with the rotation axis 110 and spin base 100, is rotated about an axis along a vertical direction in a horizontal plane.

The processing solution nozzle 112 is connected to a chemical liquid source and a pure water source through a valve. By opening the valve, the chemical liquid such as hydrofluoric acid (HF) or pure water can be discharged from the processing solution nozzle 112 to a lower surface of the substrate W. On the other hand, the clearance between an inner wall of the rotation axis 110 and the processing solution nozzle 112 is connected to an inert gas source through a valve. By opening the valve, nitrogen gas (N₂) as an inert gas is supplied from the rotation axis 110 to the lower surface of the substrate W.

The atmosphere cutoff plate 120 is a disk-like member which is so provided as to face the spin base 100. The rotation axis 121 is provided, extending upward from the center portion of the upper side of the atmosphere cutoff plate 120. The inside of the rotation axis 121 is hollow, in which a processing solution nozzle 122 is inserted. The rotation axis 121 is communicated with the motor 129. When the motor 129 is driven, the atmosphere cutoff plate 120 is rotated about an axis along a vertical direction through the rotation axis 121 in a horizontal plane. In summary, the atmosphere cutoff plate 120 is rotated in parallel to the substrate W about the same axis at the same number of revolutions.

The processing solution nozzle 122 is connected to a chemical liquid source and a pure water source through a valve. By opening the valve, the chemical liquid such as hydrofluoric acid (HF) or pure water can be discharged from the processing solution nozzle 122 to a top surface of the substrate W. On the other hand, the clearance between an inner wall of the rotation axis 121 and the processing solution nozzle 122 is connected to an inert gas source through a valve. By opening the valve, nitrogen gas as an inert gas is supplied from the rotation axis 121 to the top surface of the substrate W. It is therefore possible to supply processing solutions and nitrogen gas from both the upper and lower sides to the substrate W held by the chuck pins 101 of the spin base 100.

The cup 130 surrounds the atmosphere around the spin base 100, the substrate W held thereon, the atmosphere cutoff plate 120 and the like, and as shown in FIG. 5, forms splash guards 131 and 132. The splash guards 131 and 132 have a function of receiving the processing solution so as not to splash the processing solution spun off from the peripheral portion of the substrate W through rotation of the spin base 100 and the atmosphere cutoff plate 120 into the apparatus. The splash guards 131 and 132, thanks to their shape, form a recovery duct 140 serving as a duct for the received processing solution, to guide the processing solution toward a lower portion of the cup 130. The conducted processing solution is drained from a drain port provided on a bottom portion of the cup 130 and recovered.

Other than the above-described elements, the substrate processing apparatus is provided with, e.g., a mechanism for vertically moving the cup 130, a mechanism for vertically moving the atmosphere cutoff plate 120 or the like. These constituent elements are used to control, e.g., relative positions between the cup 130 and the substrate W or between the substrate W and the atmosphere cutoff plate 120 in accordance with stages of the processing.

As a procedure for processing the substrate W in the substrate processing apparatus, first, a not-shown transfer robot transfers an unprocessed substrate W to the spin base 100 and the chuck pins 101 hold its edge portion to keep the substrate W in a horizontal position. Next, the atmosphere cutoff plate 120 becomes closer to the spin base 100 to cover a portion over the substrate W and the cup 130 is so positioned as to surround the atmosphere around the spin base 100 and the atmosphere cutoff plate 120 (for example, in the positional relation shown in FIG. 5).

After that, the spin base 100 and the atmosphere cutoff plate 120 are rotated. With rotation of the spin base 100, the substrate W held thereon is naturally rotated. Then, in this state, the processing solution nozzle 112 discharges chemical liquid to the lower surface of the substrate W while the processing solution nozzle 122 discharges chemical liquid to the top surface of the substrate W. In other words, the chemical liquids are discharged to the substrate W from its upper and lower sides, and the discharged chemical liquids are spread entirely on both the front and back surfaces of the substrate W by centrifugal forces of rotation, with which cleaning (etching) is performed.

After finishing the cleaning process with the chemical liquid which takes a predetermined time, the processing solution nozzles 112 and 122 discharge pure water. The discharged pure water is spread entirely on both the front and back surfaces of the substrate W by centrifugal forces of rotation, with which cleaning (rinsing) is performed.

In the etching process and the rinsing process, the processing solution splashed from the spin base 100 and the like goes toward the recovery duct 140 formed of the splash guards 131 and 132 and is received by an inner surface (lower surface) of the splash guard 131 and a top surface of the splash guard 132, guided to the lower portion of the cup 130 and drained.

After finishing the cleaning process with the pure water which takes a predetermined time, the discharge of processing solution from the processing solution nozzles 112 and 122 is stopped while the substrate W is continued to rotate and waterdrops deposited on the substrate W are spun off by centrifugal forces (spin-dry process). At this time, nitrogen gas is sprayed onto the lower surface of the substrate W from the rotation axis 110 while nitrogen gas is sprayed onto the top surface of the substrate W from the rotation axis 121. With supply of nitrogen gas, the substrate W is surrounded by atmosphere of low oxygen concentration, and by performing the spin-dry process in this atmosphere, it is possible to suppress appearance of watermark (poor drying caused by reaction of water, oxygen and silicon of the substrate).

The above discussion is made on a sheet-fed substrate processing apparatus for performing both-side cleaning, and discussion on a sheet-fed substrate processing apparatus for performing bevel etching is almost the same as above. In a case of bevel etching apparatus, the chemical liquid is discharged only from the processing solution nozzle 112 to the lower surface of the substrate W while no chemical liquid is discharged from the processing solution nozzle 122 in the etching process. The chemical liquid discharged from the processing solution nozzle 112 is spread entirely on the back surface of the substrate W by centrifugal forces and part of the processing solution rounded to the peripheral portion of the front surface of the substrate W. With this rounded chemical liquid, etching of the peripheral portion of the front surface of the substrate W is performed. Processing other than the etching is almost the same as that in the above-discussed both-side cleaning process.

In summary, the background-art substrate processing apparatus has a constitution in which the processing solution used in bevel etching or cleaning has to be spun off by rotating the spin base 100, the substrate W, the atmosphere cutoff plate 120 and the like.

In the background-art sheet-fed substrate processing apparatus, however, the atmosphere near end portion of the top surface of the atmosphere cutoff plate 120 and near end portion of the lower surface of spin base 100 is involved in the recovery duct 140 used for recovery of the processing solution with rotation of the atmosphere cutoff plate 120 and the spin base 100 and forms turbulence in the recovery duct 140. With this turbulence, the processing solution which is once spun off from the substrate W is disadvantageously returned to the substrate W and redeposited on the substrate W.

In the substrate processing apparatus for performing both-side cleaning, when the processing solution which is once removed from the substrate W is redeposited on the substrate W, this becomes a cause of delay of particle deposition or drying. In the sheet-fed substrate processing apparatus for performing bevel etching, when the processing solution used in etching is deposited on the surface of the substrate W, an inviolable region (non-etching region) guarded by the atmosphere cutoff plate 120 is etched and this becomes a cause of producing defective substrates.

In order to solve these problems, there is a possible measure, e.g., of providing a lot of exhausts. This case, however, disadvantageously causes not only necessity of enormous capacity of exhaust but also a decrease in recovery efficiency of processing solution since the processing solution is sucked out by exhaust of air.

### SUMMARY OF THE INVENTION

The present invention is intended for a technique on a substrate processing apparatus which performs processing on semiconductor substrates, glass substrates for liquid crystal display, glass substrates for photomask, substrates for optical disk or the like (hereinafter, referred to simply as“substrates”) held on a rotating base with processing solutions such as chemical liquids while rotating the substrates in a horizontal plane, and more particularly on a sheet-fed substrate processing apparatus.

According to a preferred embodiment of the present invention, a substrate processing apparatus for processing a substrate with a plurality of processing solutions having different components comprises: a holding element provided on a rotating base, for holding a peripheral portion of a substrate to keep the substrate in a substantially-horizontal position; a rotation element for rotating the substrate held by the holding element about an axis along a substantially-vertical direction; an atmosphere cutoff plate positioned above the holding element, facing a top surface of the substrate held by the holding element; and a splash prevention element for receiving the plurality of processing solutions splashed from the peripheral portion of the substrate held by the holding element, and in the substrate processing apparatus, the splash prevention element comprises a plurality of recovery ducts used for collecting the plurality of processing solutions; a plurality of guiding members for forming the plurality of recovery ducts so that a vertical spacing of each opening thereof is not less than a distance between the rotating base and the atmosphere cutoff plate; and a selection element for selecting one of the recovery ducts to be used for collecting a processing solution used in a processing for the substrate, to determine a selected recovery duct, and a level of a top surface of a guiding member used for forming the selected recovery duct is set not higher than a level of a top surface of the atmosphere cutoff plate near an opening of the selected recovery duct.

Since this invention makes it possible to prevent outer atmosphere above the atmosphere cutoff plate from being involved into the selected recovery duct, it is possible to suppress redeposition of the processing solution onto the substrate. Further, since it is possible to prevent a plurality of processing solutions from being mixed in recovery, the recovery can be achieved with high efficiency.

According to the present invention, a substrate processing apparatus for processing a substrate with a plurality of processing solutions having different components comprises: a holding element provided on a rotating base, for holding a peripheral portion of a substrate to keep the substrate in a substantially-horizontal position; a rotation element for rotating the substrate held by the holding element about an axis along a substantially-vertical direction; an atmosphere cutoff plate positioned above the holding element, facing a top surface of the substrate held by the holding element; and a splash prevention element for receiving the plurality of processing solutions splashed from the peripheral portion of the substrate held by the holding element, and in the substrate processing apparatus, the splash prevention element comprises a plurality of recovery ducts used for collecting the plurality of processing solutions; a plurality of guiding members for forming the plurality of recovery ducts so that a vertical spacing of each opening thereof is not less than a distance between the rotating base and the atmosphere cutoff plate; and a selection element for selecting one of the recovery ducts to be used for collecting a processing solution used in a processing for the substrate, to determine a selected recovery duct, and a level of an lower surface of a guiding member used for forming the selected recovery duct is set not lower than a level of a lower surface of the rotating base near an opening of the selected recovery duct.

Since this prevents the outer atmosphere below the rotating base from being involved into the selected recovery duct, it is possible to suppress redeposition of the processing solution onto the substrate. Further, since it is possible to prevent a plurality of processing solutions from being mixed in recovery, the recovery can be achieved with high efficiency.

Preferably, the selected recovery duct has a shape curving downward, going away from a substrate with a vertical spacing almost equal to a vertical spacing of an opening thereof.

It is thereby possible to prevent the processing solution from being splashed back to the substrate.

Preferably, the selected recovery duct guides one of the plurality of processing solutions downward almost around a substrate.

This makes it possible to swiftly transfer the received processing solution to the lower place. It is therefore possible to prevent residence of the processing solution.

Further preferably, the substrate processing apparatus further comprises a suck element communicated with the selected recovery duct, for sucking one of the plurality of processing solutions.

This makes it possible to swiftly drain the collected processing solution.

Therefore, it is an object of the present invention to prevent a substrate processing apparatus capable of preventing redeposition of processing solution removed from a substrate by centrifugal forces onto the substrate.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal section showing a construction of a substrate processing apparatus in accordance with a first preferred embodiment of the present invention;

FIG. 2 is a partially enlarged view showing a positional relation of a spin base, an atmosphere cutoff plate and a splash guard in a bevel etching process in accordance with the first preferred embodiment of the present invention;

FIG. 3 is a longitudinal section showing a construction of a substrate processing apparatus in accordance with a second preferred embodiment of the present invention;

FIG. 4 is a view showing collection of processing solutions in the substrate processing apparatus in accordance with the second preferred embodiment of the present invention; and

FIG. 5 is a longitudinal section showing a construction of a substrate processing apparatus in the background art.

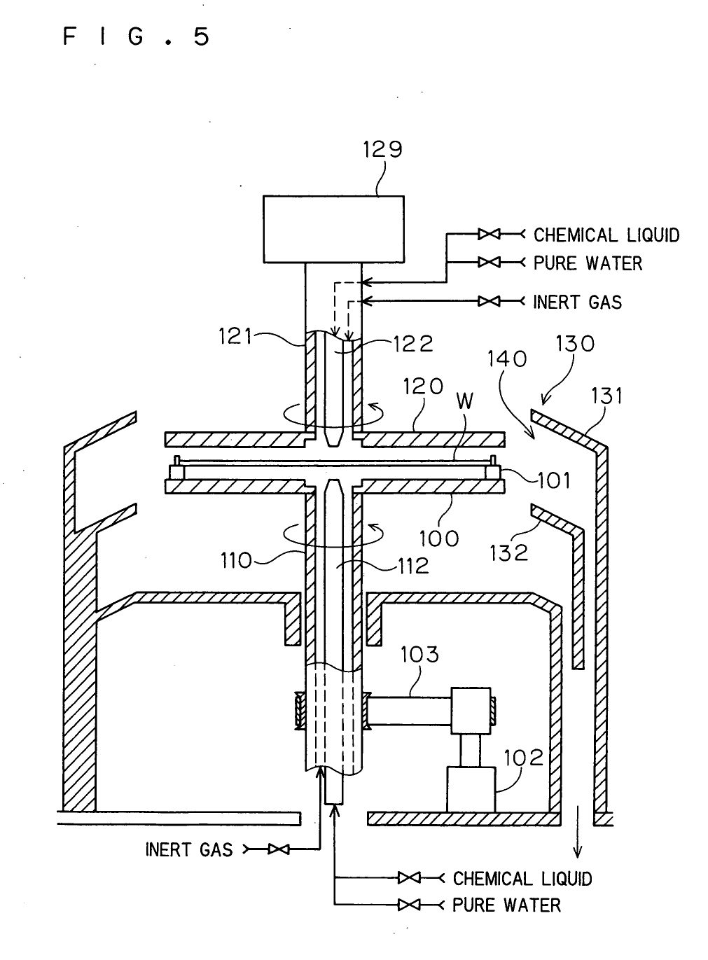

### DESCRIPTION OF THE PREFERRED EMBODIMENTS

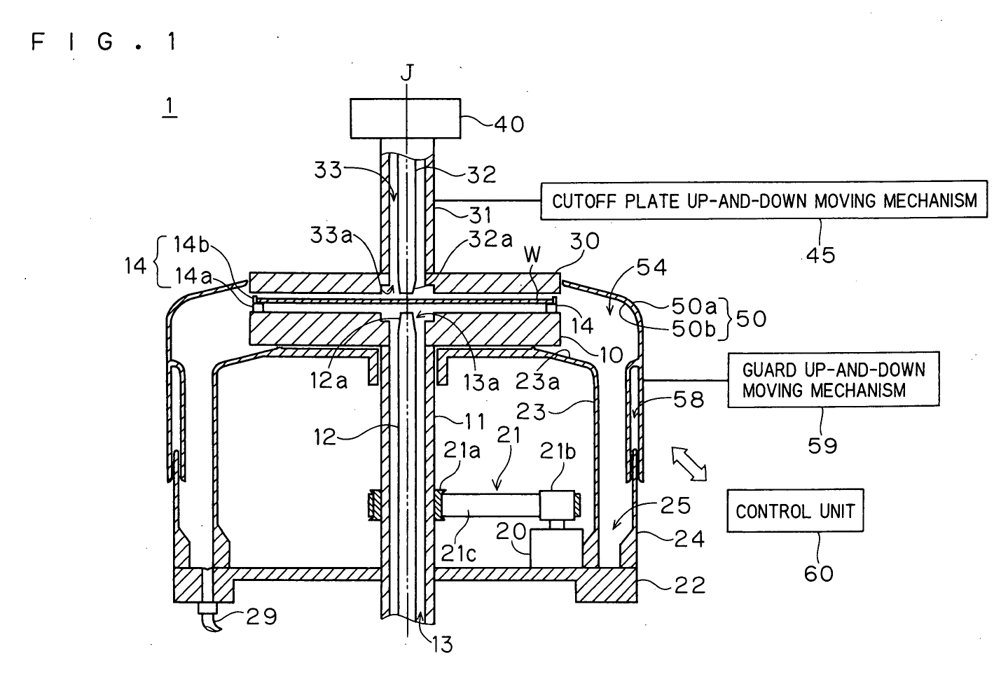

FIG. 1 is a longitudinal section showing a construction of a substrate processing apparatus 1 in accordance with the present invention. The substrate processing apparatus 1 is a sheet-fed apparatus for performing bevel etching and both-side cleaning on a substrate W and mainly comprises a spin base 10 for holding the substrate W, a plurality of chuck pins 14 provided on the spin base 10, an electric motor 20 for rotating the spin base 10, an atmosphere cutoff plate 30 which is so provided as to face the spin base 10, a splash guard 50 surrounding atmosphere around the substrate W held on the spin base 10, a mechanism for supplying a processing solution and an inert gas to the substrate W held on the spin base 10 and a mechanism for vertically moving the atmosphere cutoff plate 30 and the splash guard 50.

While the above-discussed processing is performed, the substrate W is held on the spin base 10 in a horizontal position. The spin base 10 is a disk-like member having an opening at its center portion, and its edge portion has an almost vertical side surface as shown in FIG. 1. On a top surface of the spin base 10, a plurality of chuck pins 14 for holding an edge portion of the round substrate W are provided, standing. In order to surely hold the round substrate W, three or more chuck pins 14 have to be provided, and in the substrate processing apparatus 1 of the first preferred embodiment, three chuck pins 14 stand along a rim of the spin base 10 at regular intervals (at intervals of 120 degrees). In FIG. 1, for convenience of illustration, two chuck pins 14 are shown (the same applies to the following figures).

Each of the three chuck pins 14 comprises a substrate supporting portion 14a for supporting the edge portion of the substrate W from below and a substrate holding portion 14b for holding the substrate W by pressing an outer peripheral portion of the substrate W supported by the substrate supporting portion 14a. Each chuck pin 14 has a structure to be switchable between a pressing state where the substrate holding portion 14b presses the outer peripheral portion of the substrate W and an open state where the substrate holding portion 14b comes out of touch with the outer peripheral portion of the substrate W. The switching of the three chuck pins 14 between the pressing state and the open state can be achieved by a variety of well-known mechanisms.

The substrate processing apparatus 1 brings the three chuck pins 14 into the open state when the spin base 10 receives the substrate W and the spin base 10 releases the substrate W. On the other hand, the substrate processing apparatus 1 brings the three chuck pins 14 into the pressing state when the processing discussed later is performed on the substrate W. In the pressing state, the three chuck pins 14 hold the edge portion of the substrate W to keep the substrate W in a horizontal position away from the spin base 10 with a predetermined space. At this time, the substrate W is held with its front surface upward and its back surface downward. When the three chuck pins 14 are in the pressing state to hold the substrate W, upper tip portions of the substrate supporting portions 14a protrude from the top surface of the substrate W. This prevents the substrate W from falling off from the chuck pins 14, to surely hold the substrate W, during the processing.

The rotation axis 11 is provided, extending downward from the center portion of the lower side of the spin base 10. The rotation axis 11 is a cylindrical member whose inside is hollow, in which a lower processing solution nozzle 12 is inserted. The electric motor 20 is communicated with a portion of the rotation axis 11 near its lower end through a belt drive mechanism 21. Specifically, a belt 21c is wound between a driven pulley 21a fixed around the perimeter of the rotation axis 11 and a driving pulley 21b communicated with a rotation axis of the electric motor 20. When the electric motor 20 is driven, the driving force is transferred to the rotation axis 11 through the belt drive mechanism 21, and the substrate W held by the chuck pins 14, together with the rotation axis 11 and spin base 10, is rotated about an axis J along a vertical direction in a horizontal plane.

The lower processing solution nozzle 12 penetrates the rotation axis 11, and its tip portion 12a is positioned immediately below the center portion of the substrate W held by the chuck pins 14 and its base end portion is communicated with a not-shown processing solution supply mechanism. This construction makes it possible to discharge/supply selectively either of chemical liquid and pure water (which correspond to a plurality of processing solutions) to the center portion of the lower surface of the substrate W held by the chuck pins 14 and its vicinity from the tip portion 12a of the lower processing solution nozzle 12. Thought hydrofluoric acid (HF), buffer hydrofluoric acid (BHF), SC1 (a mixed solution of aqueous ammonia, oxygenated water and water), SC2 (a mixed solution of hydrochloric acid, oxygenated water and water) or the like are used as the chemical liquid in the substrate processing apparatus 1, the chemical liquid is not limited to these.

The clearance between an inner wall of the hollow portion of the rotation axis 11 and an outer wall of the lower processing solution nozzle 12 serves as a gas supply line 13 and a tip portion 13a of the gas supply line 13 is directed to the center portion of the lower surface of the substrate W held by the chuck pins 14. Further, a base end portion of the gas supply line 13 is communicated with a not-shown inert gas source. This construction allows the substrate processing apparatus 1 to supply an inert gas to the center portion of the lower surface of the substrate W held by the chuck pins 14 from the tip portion 13a of the gas supply line 13. In the substrate processing apparatus 1, nitrogen gas (N₂) is used as the inert gas.

The above-described constituents, i.e., the rotation axis 11, the belt drive mechanism 21, the electric motor 20 and the like are accommodated in a cylindrical casing 23 provided on a base member 22.

The atmosphere cutoff plate 30 is provided above the spin base 10. The atmosphere cutoff plate 30 is a disk-like member having an opening at its center portion, and its edge portion has an almost vertical side surface as shown in FIG. 1. The atmosphere cutoff plate 30 is so provided above the chuck pins 14 as to face the top surface of the substrate W held by the chuck pins 14.

A rotation axis 31 is provided, extending upward from a center portion of the upper side of the atmosphere cutoff plate 30. The rotation axis 31 is a cylindrical member whose inside is hollow, in which an upper processing solution nozzle 32 is inserted. A rotation mechanism 40 is communicated with the rotation axis 31, and when the rotation mechanism 40 is driven, the rotation axis 31 and the atmosphere cutoff plate 30 are rotated about the axis J along the vertical direction in a horizontal plane. Therefore, the atmosphere cutoff plate 30 is rotated almost in parallel to the substrate W about the same axis. Further, the atmosphere cutoff plate 30 is rotated at almost the same number of revolutions as that of the substrate W.

The upper processing solution nozzle 32 penetrates the rotation axis 31, and its tip portion 32a is positioned immediately above the center portion of the substrate W held by the chuck pins 14 and its base end portion is communicated with a not-shown processing solution supply mechanism. This construction makes it possible to discharge/supply selectively chemical liquid or pure water to the center portion of the top surface of the substrate W held by the chuck pins 14 and its vicinity from the tip portion 32a of the upper processing solution nozzle 32.

In other words, the substrate processing apparatus 1 can use a plurality of processing solutions having different components, such as chemical liquid and pure water, and in general, selectively uses one of them to perform processing on the substrate W.

The clearance between an inner wall of the hollow portion of the rotation axis 31 and an inner wall of the opening in the center of the atmosphere cutoff plate 30 and an outer wall of the upper processing solution nozzle 32 serves as a gas supply line 33. A tip portion 33a of the gas supply line 33 is directed to the center portion of the top surface of the substrate W held by the chuck pins 14. The base end portion of the gas supply line 33 is communicated with a not-shown inert gas supply mechanism. This construction allows the substrate processing apparatus 1 to supply an inert gas (herein, nitrogen gas) to the center portion of the top surface of the substrate W held by the chuck pins 14 from the tip portion 33a of the gas supply line 33.

The atmosphere cutoff plate 30, the rotation axis 31 and the rotation mechanism 40 are vertically movable by virtue of a cutoff plate up-and-down moving mechanism 45. As the cutoff plate up-and-down moving mechanism 45, a variety of well-known mechanisms, such as a feed screw mechanism using ball screws or a mechanism using an air cylinder can be used. More specifically, the cutoff plate up-and-down moving mechanism 45 allows the atmosphere cutoff plate 30 to vertically move between a position close to the top surface of the substrate W held by the chuck pins 14 and a position above far away from the top surface of the substrate W.

A cylindrical partition member 24 is provided, standing, around the casing 23 on the base member 22. The space between an outer wall of the casing 23 and an inner wall of the partition member 24 forms a drain bath 25.

A bottom portion of the drain bath 25 is communicated with a recovery drain 29. The recovery drain 29 sucks air in the drain bath 25 to drain the used chemical liquid, pure water and gas from the drain bath 25. The pure water and gas drained by the recovery drain 29 are subjected to gas-liquid separation and thereafter are each discarded or recovered in accordance with a predetermined procedure.

When the used chemical liquid is recovered, the chemical liquid is collected into an outside recovery tank and the collected chemical liquid is supplied from the recovery tank to the processing solution supply mechanism, to be recycled.

The splash guard 50 is provided above the partition member 24. The splash guard 50 is a tubular member and so arranged as to surround the atmosphere of the spin base 10 and the substrate W held thereon. In an inner wall of the splash guard 50, a guiding part 50b is formed and an annular trench 58 is engraved.

The splash guard 50 is connected to a guard up-and-down moving mechanism 59 through a link member and is vertically movable by virtue of the guard up-and-down moving mechanism 59. As the guard up-and-down moving mechanism 59, a variety of well-known mechanisms, such as a feed screw mechanism using ball screws or a mechanism using an air cylinder can be used. When the guard up-and-down moving mechanism 59 moves the splash guard 50 upward, the guiding part 50b is positioned around the substrate W held on the spin base 10. In this state, the splash guard 50 collects the processing solution, and as discussed later in more detail, the chemical liquid or the pure water splashed from the rotating substrate W and the like is received by the guiding part 50b, flows in the drain bath 25 along a slope and is drained into the recovery drain 29.

On the other hand, when the guard up-and-down moving mechanism 59 moves the splash guard 50 downward, the partition member 24 is further housed along the trench 58, and the atmosphere cutoff plate 30 and the substrate W are exposed outside the splash guard 50.

The spin base 10, the chuck pin 14 and the electric motor 20 mainly correspond to the rotating base, the holding element and the rotation element of the present invention, respectively. The splash guard 50 and the casing 23 correspond to the splash prevention element. The guiding part 50b, a top surface 23a of the casing 23 and the partition member 24 correspond to the guiding member.

Next discussion will be made on process steps in processing on the substrate W with a processing solution by the substrate processing apparatus 1 of the first preferred embodiment having the above-discussed constitution, taking the case of performing bevel etching as an example. The basic procedure for bevel etching is to perform etching on a back surface of the substrate W with chemical liquid.

First, prior to bevel etching, loading of the substrate W is performed. In the loading process, the guard up-and-down moving mechanism 59 moves the splash guard 50 downward, to protrude the spin base 10 from the splash guard 50. Further, the cutoff plate up-and-down moving mechanism 45 significantly moves the atmosphere cutoff plate 30 upward, to bring the atmosphere cutoff plate 30 far away from the spin base 10. In this state, the unprocessed substrate W is transferred to the spin base 10 by a not-shown transfer robot. Then, the three chuck pins 14 hold the edge portion of the loaded substrate W to keep the substrate W in a horizontal position. As discussed above, when the chuck pins 14 hold the edge portion of the substrate W, the upper tip portions of the substrate supporting portion 14a protrude from the top surface of the substrate W.

Next, the splash guard 50 is moved upward to position the guiding part 50b around the spin base 10 and the substrate W held thereon and the atmosphere cutoff plate 30 is moved downward to become closer to the substrate W. The atmosphere cutoff plate 30, however, is out of touch with the chuck pins 14 and the substrate W.

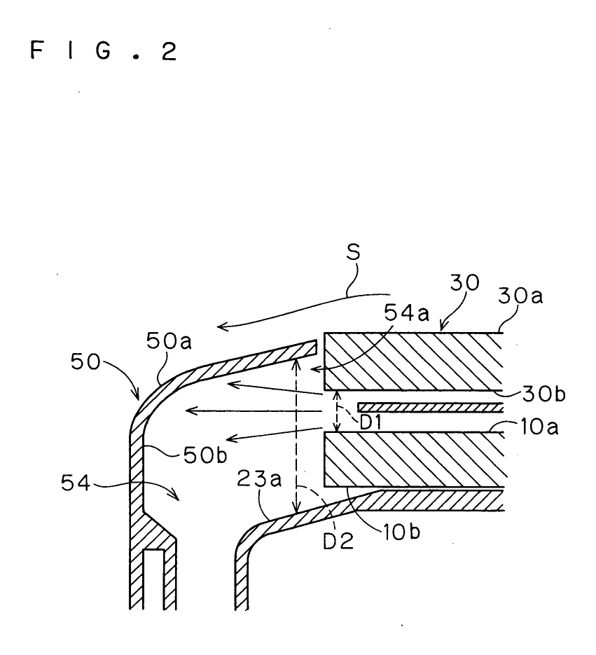

FIG. 2 is a view showing a positional relation of the spin base 10, the atmosphere cutoff plate 30 and the splash guard 50 in detail. As shown in FIG. 2, the guard up-and-down moving mechanism 59 moves the splash guard 50 upward so that the level of a top surface 50a of the splash guard 50 should not be higher than the level of a top surface 30a of the atmosphere cutoff plate 30 near the atmosphere cutoff plate 30. Thus, when the splash guard 50 is moved upward, the space between the guiding part (lower surface) 50b of the splash guard 50 and a top surface 23a of the casing 23 forms a recovery duct 54 for the chemical liquid.

The level of the splash guard 50 is set so that a vertical spacing D2 of an opening 54a of the recovery duct 54 should not be smaller than a distance D1 between the top surface 10a of the spin base 10 and the lower surface 10b of the atmosphere cutoff plate 30. Since it is preferable, however, that the vertical spacing D2 should be large in order to prevent the chemical liquid from smashing on the guiding part 50b and splashing back to the substrate W, it is preferable that the level of the splash guard 50 should be set as high as possible within the limits where the above condition is satisfied. Further, it is preferable that the clearance between the atmosphere cutoff plate 30 and the spin base 10 should be as small as possible and is set not larger than the distance D1.

In the positional relation of FIG. 2, with rotation of the spin base 10 by driving the electric motor 20, the substrate W held on the spin base 10 is rotated. The substrate processing apparatus I rotates the substrate W while rotating the atmosphere cutoff plate 30. In this state, the chemical liquid is discharged from the lower processing solution nozzle 12 to the lower surface of the substrate W. The discharged chemical liquid is spread entirely on the back surface of the substrate W by centrifugal forces of rotation, and the etching with the chemical liquid thereby proceeds. At this time, it is also possible to prevent backflow of the chemical liquid to the gas supply line 13 by discharging a small amount of nitrogen gas from the gas supply line 13.

When the rotation of the spin base 10 and the atmosphere cutoff plate 30 is started, the chemical liquid spun off from the rotating spin base 10 and substrate W by centrifugal forces is splashed from the opening 54a into the recovery duct 54 as indicated by a solid arrow of FIG. 2. At this time, in the substrate processing apparatus 1, the top surface 30a of the atmosphere cutoff plate 30 is set at a level higher than the top surface 50a of the splash guard 50 as discussed above. Therefore, even if airflow S toward the end portion of the atmosphere cutoff plate 30 occurs through rotation of the atmosphere cutoff plate 30, the airflow S is hardly involved in the recovery duct 54. In other words, in the substrate processing apparatus 1, with the above-discussed positional relation between the splash guard 50 and the atmosphere cutoff plate 30, the thickness of the atmosphere cutoff plate 30 closes the opening 54a (the distance between the splash guard 50 and the atmosphere cutoff plate 30 becomes shorter than that in the background-art apparatus) and the airflow S is not prevented, and therefore it is possible to prevent the outer atmosphere from flowing in the recovery duct 54.

Since this prevents turbulence in the recovery duct 54, it is possible to prevent the chemical liquid splashed into the recovery duct 54 from being splashed back to the substrate W due to turbulence. This further prevents redeposition of the chemical liquid onto the substrate W. In the bevel etching process, since only the back surface of the substrate W is etched, if the redeposited chemical liquid comes in through the clearance between the spin base 10 and the atmosphere cutoff plate 30, the top surface of the substrate W which is an inviolable (not-etching) region is etched, to produce a defective substrate, as discussed earlier. The substrate processing apparatus 1 of the first preferred embodiment, which can prevent redeposition of chemical liquid, is an effective apparatus especially for bevel etching.

As shown in FIG. 2, the chemical liquid splashed in the recovery duct 54 is moved in an almost horizontal direction by centrifugal forces with no effect of turbulence. In the substrate processing apparatus 1, the recovery duct 54 has a shape curving downward, going away from the substrate W to the periphery thereof with a vertical spacing almost equal to a vertical spacing of the opening 54a. Therefore, the chemical liquid splashed into the recovery duct 54 and moved by almost horizontal centrifugal forces is smashed against the guiding part 50b at a position far away from the substrate W and received.

Accordingly, a mist of chemical liquid or the like caused by smash is formed at a position relatively far away from the substrate W. Therefore, it is possible to prevent the chemical liquid from being splashed back to the substrate W as compared with the case where the chemical liquid is received at a position relatively close to the substrate W.

The chemical liquid received by the guiding part 50b is guided downward along its curve and flows into the drain bath 25 (FIG. 1). In the substrate processing apparatus 1, since the recovery duct 54 is directed downward almost around the substrate W, the received chemical liquid can be swiftly transferred downward to the drain bath 25, not remaining in the recovery duct 54. The chemical liquid flowing into the drain bath 25 is sucked by the recovery drain 29, drained and recovered, as discussed above.

After the etching which takes a predetermined time is finished, the substrate processing apparatus 1 stops the discharge of the chemical liquid from the lower processing solution nozzle 12, to finish the bevel etching process. In the substrate processing apparatus 1 of the first preferred embodiment, subsequent to the bevel etching process, the both-side cleaning process and the spin-dry process are performed. These processes may be performed by other apparatus.

After the both-side cleaning process is finished and the spin-dry process which takes a predetermined time is finished, the rotation of the spin base 10 and the substrate W held thereon is stopped and the rotation of the atmosphere cutoff plate 30 is also stopped. Then, the cutoff plate up-and-down moving mechanism 45 moves the atmosphere cutoff plate 30 upward to be far away from the spin base 10 while the guard up-and-down moving mechanism 59 moves the splash guard 50 downward. In this state, the not-shown transfer robot takes the processed substrate W out from the spin base 10 and transfers it, to complete a series of process steps.

Thus, in the substrate processing apparatus 1 of the first preferred embodiment, during a period while the splash guard 50 collects the processing solution, the vertical spacing D2 of the opening 54a is set not smaller than the distance D1 between the spin base 10 and the atmosphere cutoff plate 30 and the level of the top surface 50a of the splash guard 50 is set not higher than the level of the top surface 30a of the atmosphere cutoff plate 30, and this avoids the phenomenon in which the atmosphere above the atmosphere cutoff plate 30 is involved into the recovery duct 54 and prevents redeposition of the processing solution onto the substrate W. It is therefore possible to prevent redeposition of the processing solution onto the substrate W without necessity of exhausting a lot of air from the recovery drain 29.

Further, since the recovery duct 54 has a shape curving downward, going away from the substrate W to the periphery thereof with a vertical spacing almost equal to a vertical spacing of the opening 54a, it is possible to prevent the processing solution from being splashed back to the substrate W.

Furthermore, since the recovery duct 54 is directed downward almost around the substrate W, the received processing solution can be swiftly transferred downward to the drain bath 25. It is thereby possible to prevent the processing solution from remaining and redepositing onto the substrate W through splash.

Since the recovery drain 29 sucks the processing solution, it is possible to swiftly drain the processing solution collected in the drain bath 25.

Though an apparatus (substrate processing apparatus 1) which comprises one recovery duct for collecting the processing solution such as chemical liquid and pure water has been discussed in the first preferred embodiment, the present invention is not limited to such an apparatus but may be applied to an apparatus which has a plurality of recovery ducts.

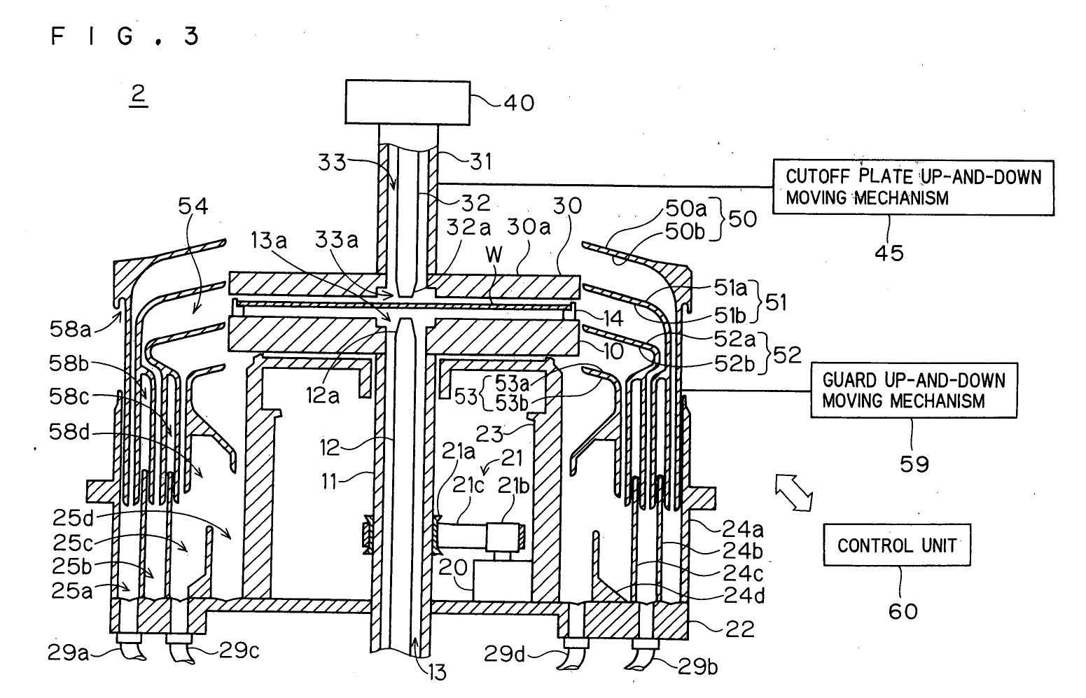

FIG. 3 is a longitudinal section showing a construction of a substrate processing apparatus 2 in accordance with the second preferred embodiment of the present invention on the above principle. In description on the substrate processing apparatus 2 of the second preferred embodiment, the constituent elements having almost the same functions as those in the substrate processing apparatus 1 of the first preferred embodiment are represented by the same reference signs and discussion thereon will be omitted as appropriate.

The substrate processing apparatus 2 is an apparatus for performing processing with processing solution, such as bevel etching and both-side cleaning, on the substrate W while rotating the substrate W held on the spin base 10, like the substrate processing apparatus 1. The substrate processing apparatus 2 comprises a plurality of splash guards 50 to 53 and forms a plurality of internal spaces away from one another by appropriately controlling their respective levels.

The splash guards 50 to 53 are vertically movable along trenches 58a to 58d provided therefor, respectively, by virtue of the guard up-and-down moving mechanism 59, and the respective levels are controlled on the basis of a control signal from a control unit 60 as necessary. Specifically, in the substrate processing apparatus 2, one of the splash guards selected by the control unit 60 is vertically moved to a level discussed later by the guard up-and-down moving mechanism 59, and an internal space formed by using the selected splash guard is selected as the recovery duct 54 which serves to collect a processing solution. In the state of FIG. 3, an internal space formed by the splash guards 51 and 52 is selected as the recovery duct 54. In other words, the control unit 60 and the guard up-and-down moving mechanism 59 correspond to the selection element of the present invention.

Further, as shown in FIG. 3, end positions of the splash guards 50 to 53 (end positions on a side close to the atmosphere cutoff plate 30) are set at almost the same positions in a vertical direction. In other words, openings of the recovery ducts which are vertically stacked are disposed at the same position in the vertical direction.

Internal spaces formed by the splash guards 50 to 53 and the casing 23 are communicated with drain baths 25a to 25d, regardless of the levels of the splash guards 50 to 53, and the drain baths 25a to 25d are separated from one another by partition members 24a to 24d. On respective lower sides of the drain baths 25a to 25d, recovery drains 29a to 29d are provided independently from one another.

With the construction in which a plurality of recovery ducts are provided, the substrate processing apparatus 2 can separate recovery paths of solutions from one another even if an internal space communicated with any one of the drain baths 25a to 25d is selected as the recovery duct 54. Specifically, even if a plurality of processing solutions having different components are used in consecutive processes, the different processing solutions can be collected through different paths. Therefore, the processing solutions used in the consecutive different processes are not mixed in the recovery process and this eliminates necessity of separation in the later step, thereby increasing efficiency of recovery of processing solutions.

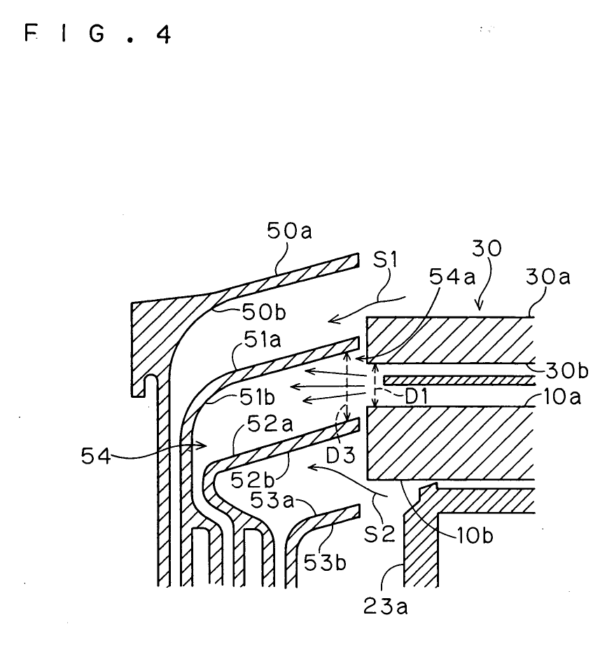

FIG. 4 is a view showing collection of chemical liquids in the substrate processing apparatus 2 in the bevel etching process. In the substrate processing apparatus 2 of the second preferred embodiment, when processing with processing solutions such as bevel etching and both-side cleaning is performed (recovery of processing solutions is needed), the control unit 60 selects the splash guard to be used for forming the recovery duct 54 among a plurality of splash guards 50 to 53 in accordance with the type of processing solution to be used and controls the guard up-and-down moving mechanism 59 to adjust the levels of the splash guards 50 to 53. Herein, discussion will be made, taking a case where the internal space between the splash guards 51 and 52 is selected as the recovery duct 54 as example.

First, the splash guard 50 not to be used is moved upward to such a level as not to interfere with the splash guard 51 while the level of a top surface 51 a of the splash guard 51 is controlled to be not higher than the level of the top surface 30a of the atmosphere cutoff plate 30 near the atmosphere cutoff plate 30 (near the opening 54a of the recovery duct 54).

Next, the level of a guiding part (lower surface) 52b of the splash guard 52 is controlled to be not lower than the level of the lower surface 10b of the spin base 10 near the spin base 10 (near the opening 54a of the recovery duct 54).

Further, at this time, the levels of the splash guards 51 and 52 are controlled so that a vertical spacing D3 of the opening 54a of the recovery duct 54 formed by the splash guards 51 and 52 should be larger than the distance D1 between the spin base 10 and the atmosphere cutoff plate 30.

Furthermore, the splash guard 53 is controlled to be positioned lower to such a degree as not to interfere with the splash guard 52.

Thus, after control of the levels of the splash guards 50 to 53 is finished, the spin base 10 is rotated by driving the electric motor 20 while the atmosphere cutoff plate 30 is also rotated. Further, the chemical liquid is discharged from the lower processing solution nozzle 12 to the back surface of the substrate W, with which the bevel etching is performed.

The chemical liquid discharged from the lower processing solution nozzle 12 is spread entirely on the back surface of the substrate W, spun off from the edge portion of the substrate W and splashed into the recovery duct 54 by centrifugal forces. At this time, since the splash guards 51 and 52 are controlled to be the above-discussed levels, the outer atmosphere is not involved in the recovery duct 54 and the chemical liquid is received by the splash guards 51 and 52, not splashed back to the substrate W. The received chemical liquid is guided to the lower portion along an inner wall of the recovery duct 54 (the guiding part 51b and the top surface 52a), collected in the drain bath 25b, sucked by the recovery drain 29b, drained and recovered.

Though discussion on the substrate processing apparatus 2 of the second preferred embodiment has been made, taking the case where the splash guards 51 and 52 form the recovery duct 54 as an example, referring to FIG. 4, the substrate processing apparatus 2 can select the splash guards to form the recovery duct 54 by controlling the levels of the splash guards 50 to 53 with the guard up-and-down moving mechanism 59 as necessary on the basis of the control signal from the control unit 60. Specifically, the level of the top surface of the selected splash guard is controlled to be not higher than the top surface 30a of the atmosphere cutoff plate 30 near the atmosphere cutoff plate 30 (near the opening 54a of the recovery duct 54) while the level of the lower surface of the splash guard positioned below the selected splash guard is controlled to be not lower than the lower surface 10b of the spin base 10 near the spin base 10 (near the opening 54a of the recovery duct 54). Thus, a recovery duct 54 to be used for recovery is selected out of a plurality of recovery ducts 54. At this time, the vertical spacing D3 of the opening 54a of the recovery duct 54 is not smaller than the distance D1 between the spin base 10 and the atmosphere cutoff plate 30.

Further, by selecting the recovery duct 54 to be used as discussed above, the opening 54a of the recovery duct 54 is disposed, being closed by the atmosphere cutoff plate 30 and the spin base 10. This prevents the processing solution which is being collected from entering the unselected recovery ducts 54.

After the bevel etching process, subsequently the post-processes such as the both-side cleaning process and the spin-dry process are performed, and after finishing the predetermined processing, the rotation of the spin base 10 and the substrate W held thereon is stopped and the rotation of the atmosphere cutoff plate 30 is also stopped. Then, the cutoff plate up-and-down moving mechanism 45 moves the atmosphere cutoff plate 30 upward to be far away from the spin base 10 while the guard up-and-down moving mechanism 59 moves the splash guards 50 to 53 downward. In this state, the not-shown transfer robot takes the processed substrate W out from the spin base 10 and transfers it, to complete a series of process steps.

Thus, in the substrate processing apparatus 2 of the second preferred embodiment, during a period while the processing solutions such as chemical liquid and pure water are collected, the vertical spacing D3 of the opening 54a of the recovery duct 54 is set not smaller than the distance D1 between the spin base 10 and the atmosphere cutoff plate 30 and the level of the lower surface (the guiding part 52b in the case of FIG. 4) of the guiding member used for forming the recovery duct 54 is set not lower than the level of the lower surface 10b of the spin base 10 near the opening 54a, and this prevents airflow S2 (outer atmosphere) generated below the spin base 10 through rotation of the spin base 10 from being involved in the recovery duct 54 which is selected for collecting the processing solution. It is therefore possible to suppress redeposition of the processing solution onto the substrate W.

Further, since the level of the top surface (the top surface 51a in the case of FIG. 4) of the guiding member used for forming the recovery duct 54 is set not higher than the level of the top surface 30a of the atmosphere cutoff plate 30 near the opening 54a, like in the substrate processing apparatus 1 of the first preferred embodiment, it is possible to prevent airflow S1 from being involved in the recovery duct 54 and therefore possible to further suppress redeposition of the processing solution onto the substrate W.

The substrate processing apparatus 2 comprises a plurality of recovery ducts, and when a plurality of processing solutions having different components are used in consecutive processes, different recovery ducts are selected in accordance with the processing solutions and it is therefore possible to prevent the processing solutions from being mixed with one another. This achieves a recovery with high efficiency.

As shown in FIG. 4, in the substrate processing apparatus 2, since the splash guards 50 to 53, the atmosphere cutoff plate 30 and the spin base 10 are arranged so that the opening 54a of the selected recovery duct 54 should be closed by the atmosphere cutoff plate 30 and the spin base 10, it is possible to effectively prevent the processing solution to be collected from entering the recovery ducts other than the selected recovery duct.

The preferred embodiments have been discussed above. Though the discussion of the second preferred embodiment has been made on the substrate processing apparatus 2 which comprises four splash guards 50 to 53, for example, the number of splash guards is not limited to the above number.

Though the guard up-and-down moving mechanism 59 moves the splash guards 50 to 53 downward to expose the substrate W when the transfer mechanism performs loading/unloading of the substrate W in the above-discussed preferred embodiments, there may be a case where another mechanism for vertically moving the spin base 10 is provided and the mechanism moves the spin base 10 upward to expose the substrate W outside the splash guards 50 to 53.

Further, there may be another case where the splash guards 50 to 53 are fixed at regular intervals and the splash guards are vertically moved as a unit.

While the invention has been shown and described in detail, the foregoing description is in all aspects illustrative and not restrictive. It is therefore understood that numerous modifications and variations can be devised without departing from the scope of the invention.

What is claimed is:

1. A substrate processing apparatus for processing a substrate with a plurality of processing solutions having different components, comprising:
a holding element provided on a rotating base, for holding a peripheral portion of a substrate to keep said substrate in a substantially-horizontal position;
a rotation element for rotating said substrate held by said holding element about an axis along a substantially-vertical direction;
an atmosphere cutoff plate positioned above said holding element, facing a top surface of said substrate held by said holding element; and
a splash prevention element for receiving said plurality of processing solutions splashed from said peripheral portion of said substrate held by said holding element,
wherein said splash prevention element comprises
a plurality of recovery ducts used for collecting said plurality of processing solutions;
a plurality of guiding members for forming said plurality of recovery ducts so that a vertical spacing of each opening thereof is not less than a distance between said rotating base and said atmosphere cutoff plate; and
a selection element for selecting one of said recovery ducts to be used for collecting a processing solution used in a processing for said substrate, to determine a selected recovery duct, and
wherein a level of a top surface of a guiding member used for forming said selected recovery duct is set not higher than a level of a top surface of said atmosphere cutoff plate near an opening of said selected recovery duct.

2. A substrate processing apparatus for processing a substrate with a plurality of processing solutions having different components, comprising:
a holding element provided on a rotating base, for holding a peripheral portion of a substrate to keep said substrate in a substantially-horizontal position;
a rotation element for rotating said substrate held by said holding element about an axis along a substantially-vertical direction;
an atmosphere cutoff plate positioned above said holding element, facing a top surface of said substrate held by said holding element; and
a splash prevention element for receiving said plurality of processing solutions splashed from said peripheral portion of said substrate held by said holding element,
wherein said splash prevention element comprises
a plurality of recovery ducts used for collecting said plurality of processing solutions;
a plurality of guiding members for forming said plurality of recovery ducts so that a vertical spacing of each opening thereof is not less than a distance between said rotating base and said atmosphere cutoff plate; and
a selection element for selecting one of said recovery ducts to be used for collecting a processing solution used in a processing for said substrate, to determine a selected recovery duct, and
wherein a level of a lower surface of a guiding member used for forming said selected recovery duct is set not lower than a level of a lower surface of said rotating base near an opening of said selected recovery duct.

3. The substrate processing apparatus according to claim 2, wherein
a level of a top surface of a guiding member used for forming said selected recovery duct is set not higher than a level of a top surface of said atmosphere cutoff plate.

4. The substrate processing apparatus according to claim 1, 2 or 3, wherein
said selected recovery duct has a shape curving downward, going away from a substrate with a vertical spacing almost equal to a vertical spacing of an opening thereof.

5. The substrate processing apparatus according to claim 1, 2 or 3, wherein
said selected recovery duct guides one of said plurality of processing solutions downward almost around a substrate.

6. The substrate processing apparatus according to claim 1, 2 or 3, further comprising
a suck element communicated with said selected recovery duct, for sucking said one of said plurality of processing solutions.

7. The substrate processing apparatus according to claim 1, 2 or 3, wherein
said rotating base and said atmosphere cutoff plate each have a disk-like shape and respective edge portions thereof facing said plurality of recovery ducts are vertical side surfaces.

8. The substrate processing apparatus according to claim 1, 2 or 3, wherein
respective openings of said plurality of recovery ducts which are vertically stacked are disposed at almost the same position in a vertical direction.
